(19) United States
(12) Patent Application Publication
(10) Pub. No.: US 2023/0361756 A1
(43) Pub. Date: Nov. 9, 2023

(54) ACOUSTIC WAVE DEVICE

(71) Applicant: Murata Manufacturing Co., Ltd., Nagaokakyo-shi (JP)

(72) Inventors: Kentaro NAKAMURA, Nagaokakyo-shi (JP); Katsuya DAIMON, Nagaokakyo-shi (JP)

(21) Appl. No.: 18/220,854

(22) Filed: Jul. 12, 2023

Related U.S. Application Data
(63) Continuation of application No. PCT/JP2022/003618, filed on Jan. 31, 2022.

(30) Foreign Application Priority Data
Feb. 4, 2021 (JP) 2021-016820

(51) Int. Cl. H03H 9/25; H03H 9/02; H03H 9/145; H03H 9/17; H03H 9/64

(52) U.S. Cl. CPC H03H 9/25; H03H 9/02574; H03H 9/14541; H03H 9/02559; H03H 9/171; H03H 9/64

(57) ABSTRACT

An acoustic wave device includes a crystal substrate, a silicon carbide layer on the crystal substrate, a lithium tantalate layer on the silicon carbide layer, and an interdigital transducer electrode on the lithium tantalate layer and including multiple first and second electrode fingers.

### CROSS REFERENCE TO RELATED APPLICATIONS

This application claims the benefit of priority to Japanese Patent Application No. 2021-016820 filed on Feb. 4, 2021 and is a Continuation application of PCT Application No. PCT/JP2022/003618 filed on Jan. 31, 2022. The entire contents of each application are hereby incorporated herein by reference.

### BACKGROUND OF THE INVENTION

### 1. Field of the Invention

The present invention relates to an acoustic wave device.

### 2. Description of the Related Art

Acoustic wave devices have been widely used in various purposes, such as filters for mobile phones. Japanese Unexamined Patent Application Publication No. 2019-145895 discloses an example of an acoustic wave device. This acoustic wave device includes a support substrate, a high velocity film, a low velocity film, and a piezoelectric layer laminated in this order. An interdigital transducer (IDT) electrode is disposed on the piezoelectric layer. The high velocity film is formed from SiNₓ. Here, x<0.67, and thus, the higher order mode is reduced.

### SUMMARY OF THE INVENTION

However, the acoustic wave device described in Japanese Unexamined Patent Application Publication No. 2019-145895 is not suitable for reducing a higher order mode in a wide band.

Preferred embodiments of the present invention provide acoustic wave devices each capable of reducing a higher order mode in a wide band.

An acoustic wave device according to a preferred embodiment of the present invention includes a crystal substrate, a silicon carbide layer on the crystal substrate, a piezoelectric layer on the silicon carbide layer, and an interdigital transducer electrode on the piezoelectric layer and that includes multiple electrode fingers.

An acoustic wave device according to a preferred embodiment of the present invention can reduce a higher order mode in a wide band.

The above and other elements, features, steps, characteristics and advantages of the present invention will become more apparent from the following detailed description of the preferred embodiments with reference to the attached drawings.

### BRIEF DESCRIPTION OF THE DRAWINGS

FIG. 1 is a cross-sectional view, viewed from the front, of a portion of an acoustic wave device according to a first preferred embodiment of the present invention.

FIG. 2 is a plan view of the acoustic wave device according to the first preferred embodiment of the present invention.

FIG. 3 is a schematic diagram of the coordinate systems of Euler angles.

FIG. 4 is a diagram of phase characteristics of acoustic wave devices according to the first preferred embodiment of the present invention and according to a comparative example.

FIG. 5 is a cross-sectional view, viewed from the front, of a portion of an acoustic wave device according to a modification example of the first preferred embodiment of the present invention.

FIG. 6 is a graph showing the relationship between θ in the Euler angles of a crystal substrate, a thickness t of a silicon carbide layer, and a Z ratio.

FIG. 7 is a graph showing the relationship between θ in the Euler angles of the crystal substrate within the range of about 185° to about 190°, the thickness t of the silicon carbide layer, and a phase of the higher order mode.

FIG. 8 is a graph obtained by enlarging the graph in FIG. 7 in the case where θ is within the range of about 185° to about 188°.

FIG. 9 is a graph obtained by enlarging the graph in FIG. 7 in the case where θ is within the range of about 188° to about 190°.

FIG. 10 is a graph showing the relationship between θ in the Euler angles of a crystal substrate within the range of about 190° to about 240°, the thickness t of the silicon carbide layer, and a phase of the higher order mode.

FIG. 11 is a graph obtained by enlarging the graph in FIG. 10, in the case where θ is within the range of about 190° to about 215°.

FIG. 12 is a graph obtained by enlarging the graph in FIG. 10, in the case where θ is within the range of about 215° to about 240°.

FIG. 13 a stereographic projection showing symmetry of acoustic vibrations in quartz crystal.

FIG. 14 is a graph showing a phase characteristic of acoustic wave devices according to a second preferred embodiment and a third preferred embodiment of the present invention.

### DETAILED DESCRIPTION OF THE PREFERRED EMBODIMENTS

With reference to the drawings, specific preferred embodiments of the present invention are described below with reference to the drawings to clarify the present invention.

Each preferred embodiment described herein is a mere example, and components between different preferred embodiments may be partially replaced with each other or combined with each other.

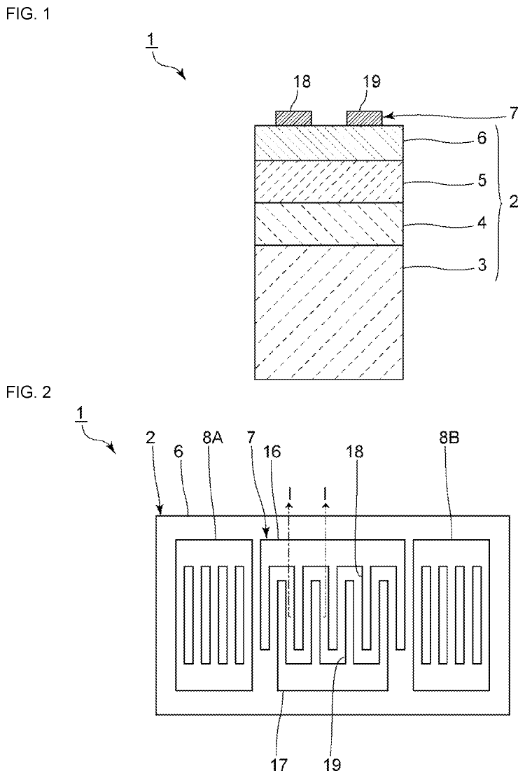

FIG. 1 is a cross-sectional view, viewed from the front, of a portion of an acoustic wave device according to a first preferred embodiment of the present invention. FIG. 2 is a plan view of the acoustic wave device according to the first preferred embodiment. FIG. 1 is a cross-sectional view taken along line I-I in FIG. 2.

As illustrated in FIG. 1, an acoustic wave device 1 includes a piezoelectric substrate 2. The piezoelectric substrate 2 includes a crystal substrate 3, a silicon carbide layer 4, a low velocity film 5, and a lithium tantalate layer 6. More specifically, the silicon carbide layer 4 is disposed on the crystal substrate 3. The low velocity film 5 is disposed on the silicon carbide layer 4. The lithium tantalate layer 6 is disposed on the low velocity film 5. The piezoelectric layer included in the piezoelectric substrate is not limited to a lithium tantalate layer, and may be a lithium niobate layer.

An IDT electrode 7 is disposed on the lithium tantalate layer 6. When an alternating current voltage is applied to the IDT electrode 7, acoustic waves are excited. As illustrated in FIG. 2, a pair of reflectors 8A and 8B are disposed on the lithium tantalate layer 6 on both sides in a propagation direction in which the acoustic waves propagate. As described above, the acoustic wave device 1 according to the present preferred embodiment is a surface acoustic wave resonator. However, the acoustic wave device according to the present invention is not limited to an acoustic wave resonator, and may be a multiplexer or a filter device including multiple acoustic wave resonators.

The low velocity film 5 illustrated in FIG. 1 is a film for a relatively low velocity. More specifically, a bulk wave that propagates through the low velocity film 5 has a lower velocity than a bulk wave that propagates through the lithium tantalate layer 6. In the present preferred embodiment, the low velocity film 5 is a silicon oxide film. The material of the low velocity film 5 is not limited to the above example. The low velocity film 5 may be formed from, for example, glass, a silicon oxynitride, a lithium oxide, a tantalum pentoxide, or a compound obtained by adding fluorine, carbon, or boron to a silicon oxide as a main component.

As described above, the piezoelectric substrate 2 includes the crystal substrate 3 and the lithium tantalate layer 6. Thus, the piezoelectric substrate 2 has a small difference in a coefficient of linear expansion, and thus can improve frequency temperature characteristics. The low velocity film 5 formed from a silicon oxide film can reduce an absolute value of the temperature coefficient of frequency (TCF) in the piezoelectric substrate 2, and thus can further improve the frequency temperature characteristics. Instead, the low velocity film 5 may be eliminated.

The lithium tantalate layer 6 preferably has a cut-angle of about 20°-rotated Y-cut X-propagation to about 60°-rotated Y-cut X-propagation. Thus, an acoustic wave element having a preferable electromechanical coupling coefficient and a preferable Q value can be obtained. Similarly, also when the piezoelectric layer is a lithium niobate layer, the lithium niobate layer preferably has a cut-angle of about 20°-rotated Y-cut X-propagation to about 60°-rotated Y-cut X-propagation.

In the present preferred embodiment, a bulk wave that propagates through the crystal substrate 3 has a lower velocity than an acoustic wave that propagates through the lithium tantalate layer 6. More specifically, a slow transversal wave that propagates through the crystal substrate 3 has a lower velocity than a surface acoustic wave that propagates through the lithium tantalate layer 6. However, the relationship in velocity between the crystal substrate 3 and the lithium tantalate layer 6 is not limited to the above.

As illustrated in FIG. 2, the IDT electrode 7 includes a first busbar 16, a second busbar 17, multiple first electrode fingers 18, and multiple second electrode fingers 19. The first busbar 16 and the second busbar 17 face each other. One end of each of the multiple first electrode fingers 18 is connected to the first busbar 16. One end of each of the multiple second electrode fingers 19 is connected to the second busbar 17. The multiple first electrode fingers 18 and the multiple second electrode fingers 19 interdigitate with one another. The IDT electrode 7, the reflector 8A, and the reflector 8B may each be formed from a multilayer metal film or a single-layer metal film.

A wavelength defined by an electrode finger pitch of the IDT electrode 7 is defined as λ. The lithium tantalate layer 6 has a thickness of smaller than or equal to about 1λ, for example. This structure can thus preferably enhance excitation efficiency. The electrode finger pitch is a center distance between adjacent electrode fingers.

One of the unique features of the present preferred embodiment is that the piezoelectric substrate 2 includes the crystal substrate 3, the silicon carbide layer 4, and the lithium tantalate layer 6. The piezoelectric substrate 2 having the above structure can set, for example, the mode of frequencies around 2.2 times of the resonant frequency to a leaky mode. This structure can thus reduce a higher order mode in a wide band. The details of this effect are described below by comparing the present preferred embodiment and a comparative example.

The comparative example differs from the first preferred embodiment in that a piezoelectric substrate is a multilayer body including a silicon substrate, a silicon nitride film, a silicon oxide film, and a lithium tantalate layer. The acoustic wave device 1 according to the first preferred embodiment and an acoustic wave device according to the comparative example are compared in terms of phase characteristics. An example of the acoustic wave device 1 according to the first preferred embodiment has design parameters below.
crystal substrate 3: Euler angles (φ, θ, ψ) of (0°, 200°, 900)
silicon carbide layer 4: a thickness of 2 μm
low velocity film 5: a material of SiO₂ and a thickness of 300 nm
lithium tantalate layer 6: a material of LiTaO₃ and a thickness of 400 nm

IDT electrode 7: a layer structure including a Ti layer, an AlCu layer, and a Ti layer sequentially laminated on the lithium tantalate layer 6, thicknesses of 12 nm, 100 nm, and 4 nm from the side closer to the lithium tantalate layer 6, a wavelength λ of 2 μm, and a duty of 0.5

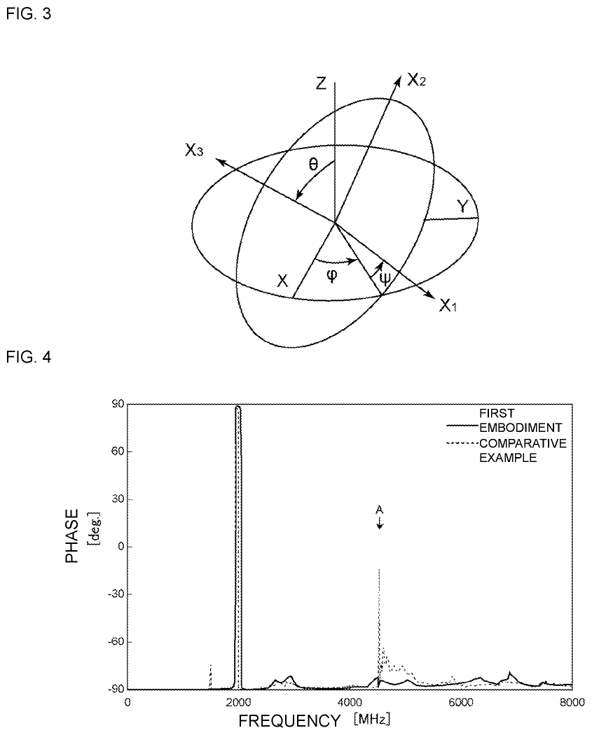

Herein, unless otherwise specified, the orientations of the crystal substrate 3 are indicated with the Euler angles. The coordinate systems of the Euler angles are coordinate systems illustrated in FIG. 3, and differ from polar coordinate systems. In FIG. 3, initial coordinate axes are indicated with an X axis, a Y axis, and a Z axis, and vectors after rotations at φ°, θ°, and ψ° are indicated with X₁, X₂, and X₃.

FIG. 4 is a diagram of phase characteristics of acoustic wave devices according to the first preferred embodiment of the present invention and according to a comparative example.

As indicated with arrow A in FIG. 4, a comparative example fails to reduce a higher order mode around frequencies of about 2.2 times of the resonant frequency. In contrast, the first preferred embodiment can successfully reduce a higher order mode in a wide band including a mode around frequencies of about 2.2 times of the resonant frequency.

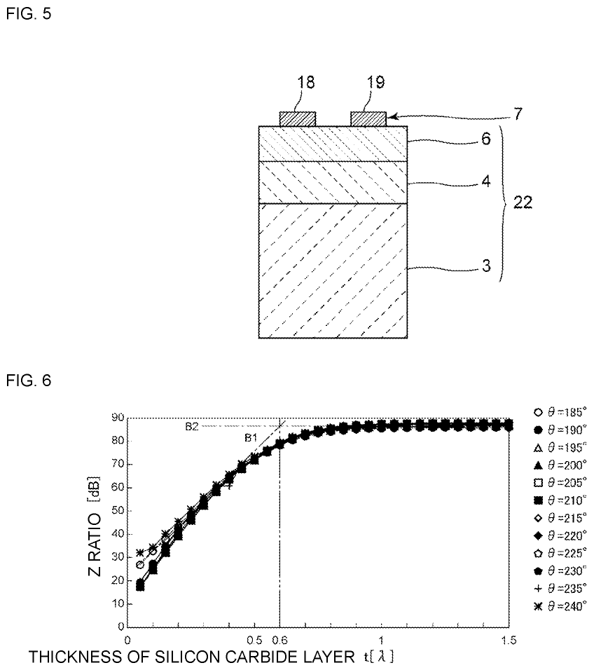

In the piezoelectric substrate 2, the lithium tantalate layer 6 is indirectly disposed on the silicon carbide layer 4 with the low velocity film 5 interposed in between. Instead, the piezoelectric substrate 2 may eliminate the low velocity film 5. For example, in a modification example for the first preferred embodiment illustrated in FIG. 5, a piezoelectric substrate 22 is a multilayer body including the crystal substrate 3, the silicon carbide layer 4, and the lithium tantalate layer 6. In the piezoelectric substrate 22, the lithium tantalate layer 6 is directly disposed on the silicon carbide layer 4. As in the case of the first preferred embodiment, this structure can also reduce a higher order mode in a wide band.

In the acoustic wave device 1 according to the first preferred embodiment, the Z ratio and the phase of a higher order mode are measured every time the thickness of the silicon carbide layer 4 is changed. The Z ratio is an impedance ratio. More specifically, the Z ratio is calculated by dividing the impedance of an anti-resonant frequency with the impedance of the resonant frequency. The phase of the measured higher order mode is a phase component of the impedance in a maximum mode in a spurious mode caused within a range of frequencies of about 1.15 times to about 3 times of the resonant frequency including frequencies of about 2.2 times of the resonant frequency, for example. The thickness of the silicon carbide layer 4 is changed in approximately 0.05λ intervals within the range greater than or equal to about 0.05λ to smaller than or equal to about 2.5λ, for example. Thus, the relationship between the thickness of the silicon carbide layer 4, the Z ratio, and the phase of the higher order mode is obtained. In the following description, the thickness of the silicon carbide layer 4 is denoted with t.

In addition, θ in the Euler angles (φ, θ, ψ) of the crystal substrate 3 is changed, and the above relationship for θ with each angle is obtained. In the Euler angles of the crystal substrate 3, φ is set at about 0°, and ψ is set at about 90°. The angle θ is changed in approximately 1° intervals within the range larger than or equal to about 185° and smaller than or equal to about 190°, and changed in approximately 5° intervals within the range larger than or equal to about 190° and smaller than or equal to about 240°.

FIG. 6 is a graph showing the relationship between θ in the Euler angles of a crystal substrate, the thickness t of the silicon carbide layer, and the Z ratio. A dot-and-dash line B1 and a dot-and-dash line B2 in FIG. 6 indicate inclination of a change of the Z ratio with respect to a change of the thickness t of the silicon carbide layer 4.

As illustrated in FIG. 6, regardless of when θ in the Euler angles of the crystal substrate 3 has any degree, the Z ratio increases further as the thickness t of the silicon carbide layer 4 increases further. As indicated with the dot-and-dash line B1 and the dot-and-dash line B2, the change of the Z ratio is reduced when t≥ about 0.6λ rather than when t< about 0.6λ. Thus, the thickness t of the silicon carbide layer 4 is preferably t≥ about 0.6λ. This structure can reduce the variation of the Z ratio, and the Z ratio can thus be increased. Thus, the electric characteristics of the acoustic wave device 1 can be stably enhanced. In addition, the thickness may preferably be t≤ about 2.5λ. In this structure, the silicon carbide layer 4 can be preferably formed, and enhance productivity.

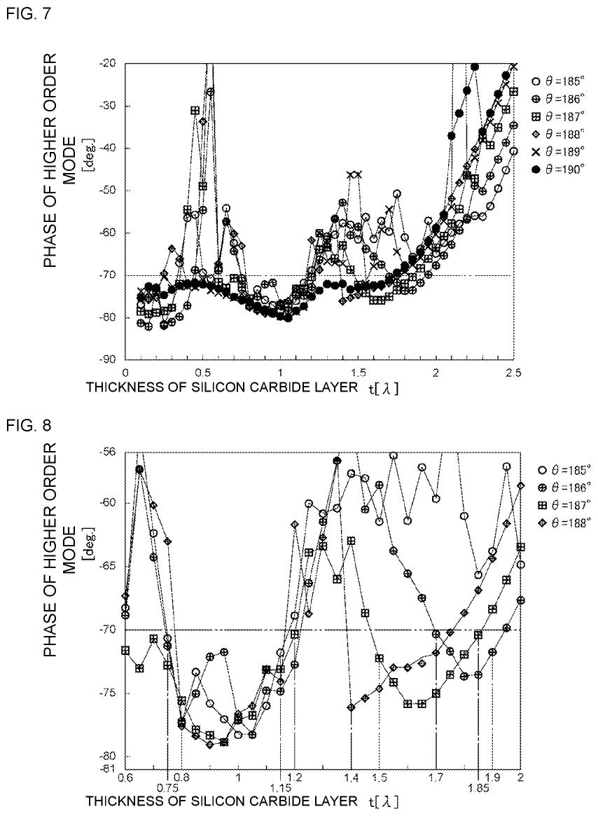

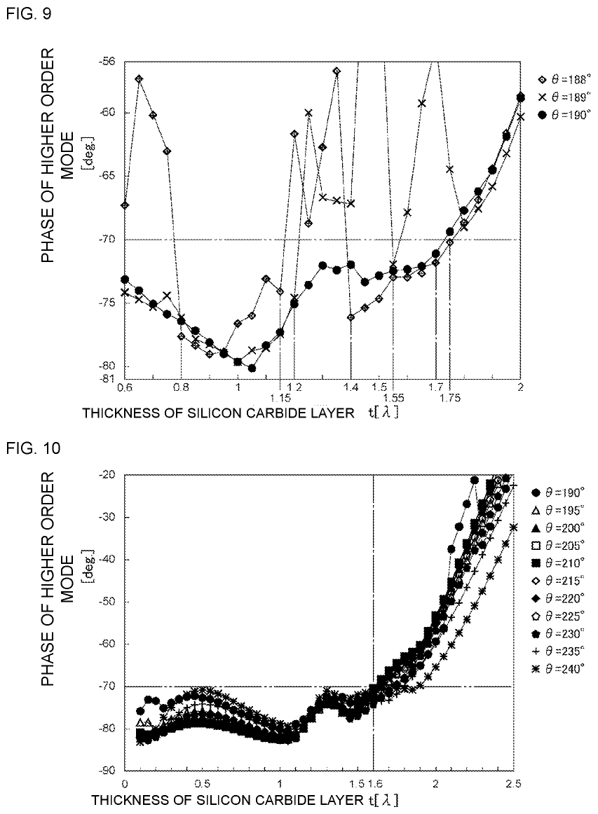

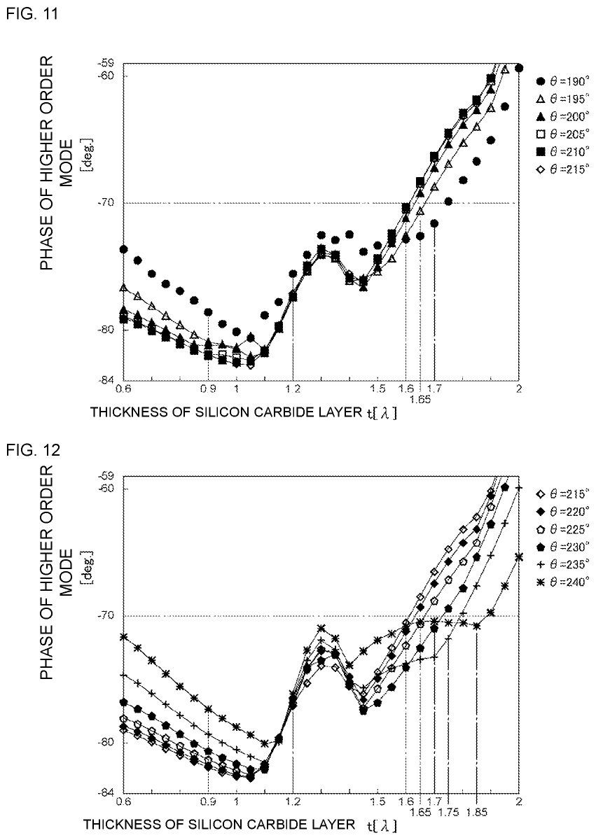

FIG. 7 is a graph showing the relationship between θ in the Euler angles of a crystal substrate within the range of about 185° to about 190°, the thickness t of the silicon carbide layer, and a phase of the higher order mode. FIG. 8 is a graph obtained by enlarging the graph in FIG. 7 in the case where θ is within the range of about 185° to about 188°. FIG. 9 is a graph obtained by enlarging the graph in FIG. 7 in the case where θ is within the range of about 188° to about 190°. FIG. 10 is a graph showing the relationship between θ in the Euler angles of a crystal substrate within the range of about 190° to about 240°, the thickness t of the silicon carbide layer, and a phase of the higher order mode. FIG. 11 is a graph obtained by enlarging the graph in FIG. 10, in the case where θ is within the range of about 190° to about 215°. FIG. 12 is a graph obtained by enlarging the graph in FIG. 10, in the case where θ is within the range of about 215° to about 240°. The phase illustrated in FIG. 7 to FIG. 12 is a phase component of the impedance of a maximum mode in a spurious mode caused within a range of frequencies of about 1.15 times to about 3 times of the resonant frequency including frequencies of about 2.2 times of the resonant frequency, for example.

As illustrated in FIG. 7, in the range where θ in the Euler angles of the crystal substrate 3 is within the range of about 185°≤θ< about 190°, the phase of the higher order mode can be reduced to smaller than about −70 deg. when the thickness t of the silicon carbide layer 4 is within the range described below. As described above, about 0.6λ≤t≤ about 2.5λ is preferable. Thus, the range where the higher order mode can be reduced is described while about 0.6λ≤t≤ about 2.5λ. When about 185°≤θ< about 190°, the thickness t where the higher order mode can be reduced is described within the range of θ± about 0.5°, for example.

As illustrated in FIG. 8, when about 185°≤θ< about 185.5°, the thickness may be about 0.75λ≤t≤ about 1.15λ. When about 185.5°≤θ< about 186.5°, the thickness may be about 0.75λ≤t≤ about 1.2λ or about 1.7λ≤t≤ about 1.9λ. When about 186.5°≤θ< about 187.5°, the thickness may be about 0.6λ≤t≤ about 1.2λ or about 1.5λ≤t≤ about 1.85λ.

As illustrated in FIG. 9, when about 187.5°≤θ< about 188.5°, the thickness may be about 0.8λ≤t≤ about 1.15λ or about 1.4λ≤t≤ about 1.75λ. When about 188.5°≤θ< about 189.5°, the thickness may be about 0.6λ≤t≤ about 1.2λ. When about 189.5°≤θ< about 190°, the thickness may be about 0.6λ≤t≤ about 1.7λ.

On the other hand, as illustrated in FIG. 10, when about 190°≤θ≤ about 240°, as long as the thickness t of the silicon carbide layer 4 satisfies t≤ about 1.6λ, the phase of the higher order mode can be reduced to be smaller than about −70 deg. The detailed range of the thickness t of the silicon carbide layer 4 where the phase of the higher order mode can be reduced to be smaller than about −70 deg. is described as below. When about 190°≤θ≤ about 240°, the range of the thickness t where the higher order mode can be reduced is shown within the range of θ± about 2.5°, for example.

As illustrated in FIG. 11, when about 190°≤θ< about 192.5°, the thickness may be about 0.6λ≤t≤ about 1.7λ. When about 192.5°≤θ< about 197.5°, the thickness may be about 0.6λ≤t≤ about 1.65λ. When about 197.5°≤θ< about 202.5°, the thickness may be about 0.6λ≤t≤ about 1.6λ. When about 202.5°θ< about 207.5°, the thickness may be about 0.6λ≤t≤ about 1.6λ. When about 207.5°≤θ< about 212.5°, the thickness may be about 0.6λ t about 1.6λ.

As illustrated in FIG. 12, when about 212.5°≤θ< about 217.5°, the thickness may be about 0.6λ≤t≤ about 1.6λ. When about 217.5°≤θ< about 222.5°, the thickness may be about 0.6λ≤t≤ about 1.6λ. When about 222.5°≤θ< about 227.5°, the thickness may be about 0.6λ≤t≤ about 1.65λ. When about 227.5°θ< about 232.5°, the thickness may be about 0.6λ≤t≤ about 1.7λ. When about 232.5°≤θ< about 237.5°, the thickness may be about 0.6λ≤t≤ about 1.75λ. When about 237.5°≤θ≤ about 240°, the thickness may be about 0.6λ≤t≤ about 1.85λ.

It is known that when φ in the Euler angles of the crystal substrate 3 is within the range of about 0°±2.5°, and when ψ is within the range of about 90°±2.5°, the effects on the Z ratio and the higher order mode are small. From the above, preferably, the Euler angles (φ, θ, ψ) of the crystal substrate 3 are (about 0°±2.5°, θ, about 90°±2.5°), and the relationship between θ in the Euler angles of the crystal substrate 3 and the thickness t of the silicon carbide layer 4 is any of the combinations in Table 1. Thus, the Z ratio can be stably increased, and the higher order mode can be effectively reduced.

TABLE 1

| θ [°] of crystal | thickness t [λ] of |
|---|---|
| substrate | silicon carbide layer |
| 185 ≤ θ < 185.5 | 0.75 ≤ t ≤ 1.15 |
| 185.5 ≤ θ < 186.5 | 0.75 ≤ t ≤ 1.2 |
| | 1.7 ≤ t ≤ 1.9 |
| 186.5 ≤ θ < 187.5 | 0.6 ≤ t ≤ 1.2 |
| | 1.5 ≤ t ≤ 1.85 |
| 187.5 ≤ θ < 188.5 | 0.8 ≤ t ≤ 1.15 |
| | 1.4 ≤ t ≤ 1.75 |
| 188.5 ≤ θ < 189.5 | 0.6 ≤ t ≤ 1.2 |
| 189.5 ≤ θ < 190 | 0.6 ≤ t ≤ 1.7 |
| 190 ≤ θ < 192.5 | 0.6 ≤ t ≤ 1.7 |
| 192.5 ≤ θ < 197.5 | 0.6 ≤ t ≤ 1.65 |
| 197.5 ≤ θ < 202.5 | 0.6 ≤ t ≤ 1.6 |
| 202.5 ≤ θ < 207.5 | 0.6 ≤ t ≤ 1.6 |
| 207.5 ≤ θ < 212.5 | 0.6 ≤ t ≤ 1.6 |
| 212.5 ≤ θ < 217.5 | 0.6 ≤ t ≤ 1.6 |
| 217.5 ≤ θ < 222.5 | 0.6 ≤ t ≤ 1.6 |
| 222.5 ≤ θ < 227.5 | 0.6 ≤ t ≤ 1.65 |
| 227.5 ≤ θ < 232.5 | 0.6 ≤ t ≤ 1.7 |
| 232.5 ≤ θ < 237.5 | 0.6 ≤ t ≤ 1.75 |
| 237.5 ≤ θ ≤ 240 | 0.6 ≤ t ≤ 1.85 |

As described above, in the first preferred embodiment, a bulk wave that propagates through the crystal substrate 3 has a lower velocity than an acoustic wave that propagates through the lithium tantalate layer 6. Thus, the crystal substrate 3 can leak a higher order mode, and thus the higher order mode can be effectively reduced. For example, the Euler angles (about 0°, about 200°, about 90°) of the crystal substrate 3 of the acoustic wave device 1 exhibiting the phase characteristic in FIG. 4 have the above velocity relationship. For example, despite when the Euler angles of the crystal substrate 3 are within the range of (φ, θ, ψ) listed in Table 2 to Table 14, a bulk wave that propagates through the crystal substrate 3 has a lower velocity than an acoustic wave that propagates through the lithium tantalate layer 6.

In Table 2 to Table 14, each of the Euler angles (φ, θ, ψ) is within the range of about ±2.5°. More specifically, in Table 2, φ is within the range of about −2.5°≤φ< about 2.5°, and in Table 3, φ is within the range of about 2.5°≤φ< about 7.5°. Thus, in Table 2 to Table 14, φ increments by approximately 5°. In Table 14, φ is within the range of about 57.5°≤φ≤ about 62.5°. Each table shows the range of θ when φ is within a fixed range, and the range of ψ is changed in approximately 5° intervals. More specifically, when, for example, ψ is described as 0° in each table, the range of θ where about −2.5°≤ψ< about 2.5° is described, and when ψ is described as about 5°, the range of θ where about 2.5°≤ψ< about 7.5° is described. When ψ is described as about 175°, the range of θ where about 172.5°≤ψ≤ about 177.5° is described. The range of θ in each table also shows the range of higher than or equal to about −2.5° of the described lower limit and smaller than or equal to about +2.5° of the described upper limit.

TABLE 2
(ϕ[°], θ[°], ψ[°])

| | | | | |
|---|---|---|---|---|
| (0, 0-175, 0) | (0, 0-175, 5) | (0, 0-175, 10) | (0, 0-175, 15) | (0, 0-15, 20) |
| (0, 65-175, 20) | (0, 85-175, 25) | (0, 90-170, 30) | (0, 90-175, 35) | (0, 0-5, 40) |
| (0, 85-175, 40) | (0, 0-10, 45) | (0, 80-175, 45) | (0, 0-15, 50) | (0, 75-175, 50) |
| (0, 0-20, 55) | (0, 65-175, 55) | (0, 0-25, 60) | (0, 55-175, 60) | (0, 0-35, 65) |
| (0, 45-70, 65) | (0, 110-140, 65) | (0, 150-175, 65) | (0, 0-65, 70) | (0, 115-135, 70) |
| (0, 165-175, 70) | (0, 0-60, 75) | (0, 120-135, 75) | (0, 170-175, 75) | (0, 0-60, 80) |
| (0, 120-130, 80) | (0, 5-60, 85) | (0, 120-130, 85) | (0, 5-60, 90) | (0, 120-130, 90) |
| (0, 5-60, 95) | (0, 120-130, 95) | (0, 0-60, 100) | (0, 120-130, 100) | (0, 0-60, 105) |
| (0, 120-135, 105) | (0, 170-175, 105) | (0, 0-65, 110) | (0, 115-135, 110) | (0, 165-175, 110) |
| (0, 0-35, 115) | (0, 45-70, 115) | (0, 110-140, 115) | (0, 150-175, 115) | (0, 0-25, 120) |
| (0, 55-175, 120) | (0, 0-20, 125) | (0, 65-175, 125) | (0, 0-15, 130) | (0, 75-175, 130) |
| (0, 0-10, 135) | (0, 80-175, 135) | (0, 0-5, 140) | (0, 85-175, 140) | (0, 90-175, 145) |
| (0, 90-170, 150) | (0, 85-175, 155) | (0, 0-15, 160) | (0, 65-175, 160) | (0, 0-175, 165) |
| (0, 0-175, 170) | (0, 0-175, 175) | | | |

TABLE 3
(ϕ[°], θ[°], ψ[°])

| | | | | |
|---|---|---|---|---|
| (5, 0-175,0) | (5, 0-175, 5) | (5, 0-175, 10) | (5, 0-25, 15) | (5, 55-175, 15) |
| (5, 85-175, 20) | (5, 95-175, 25) | (5, 100-175, 30) | (5, 0-5, 35) | (5, 100-170, 35) |
| (5, 0-15, 40) | (5, 90-175, 40) | (5, 0-20, 45) | (5, 85-175, 45) | (5, 0-25, 50) |
| (5, 75-175, 50) | (5, 0-30, 55) | (5, 65-175, 55) | (5, 0-35, 60) | (5, 50-175, 60) |
| (5, 0-70, 65) | (5, 110-175, 65) | (5, 0-65, 70) | (5, 115-140, 70) | (5, 155-175, 70) |
| (5, 0-60, 75) | (5, 120-135, 75) | (5, 165-175, 75) | (5, 5-60, 80) | (5, 120-135, 80) |
| (5, 170-175, 80) | (5, 5-60, 85) | (5, 120-130, 85) | (5, 5-60, 90) | (5, 120-130, 90) |
| (5, 0-60, 95) | (5, 120-130, 95) | (5, 0-60, 100) | (5, 120-130, 100) | (5, 0-60, 105) |
| (5, 120-130, 105) | (5, 0-65, 110) | (5, 115-135, 110) | (5, 170-175, 110) | (5, 0-25, 115) |
| (5, 50-70, 115) | (5, 110-135, 115) | (5, 160-175, 115) | (5, 0-20, 120) | (5, 60-175, 120) |
| (5, 0-15, 125) | (5, 65-175, 125) | (5, 0-10, 130) | (5, 70-175, 130) | (5, 0-5, 135) |
| (5, 75-175, 135) | (5, 80-175, 140) | (5, 85-175, 145) | (5, 85-175, 150) | (5, 0-10, 155) |
| (5, 70-170, 155) | (5, 0-175, 160) | (5, 0-175, 165) | (5, 0-175, 170) | (5, 0-175, 175) |

TABLE 4
(ϕ[°], θ[°], ψ[°])

| | | | | |
|---|---|---|---|---|
| (10, 0-175, 0) | (10, 0-175, 5) | (10, 0-175, 10) | (10, 85-175, 15) | (10, 100-175, 20) |
| (10, 105-175, 25) | (10, 0-5, 30) | (10, 110-175, 30) | (10, 0-15, 35) | (10, 110-175, 35) |
| (10, 0-20, 40) | (10, 100-170, 40) | (10, 0-25, 45) | (10, 85-175, 45) | (10, 0-30, 50) |
| (10, 75-175, 50) | (10, 0-35, 55) | (10, 60-175, 55) | (10, 0-175, 60) | (10, 0-70, 65) |
| (10, 110-175, 65) | (10, 0-65, 70) | (10, 115-175, 70) | (10, 5-60, 75) | (10, 120-140, 75) |
| (10, 155-175, 75) | (10, 5-60, 80) | (10, 120-135, 80) | (10, 165-175, 80) | (10, 5-60, 85) |
| (10, 120-135, 85) | (10, 170-175, 85) | (10, 0-60, 90) | (10, 120-130, 90) | (10, 0-60, 95) |
| (10, 120-130, 95) | (10, 0-60, 100) | (10, 120-130, 100) | (10, 0-60, 105) | (10, 120-130, 105) |
| (10, 0-25, 110) | (10, 45-65, 110) | (10, 115-130, 110) | (10, 175-175, 110) | (10, 0-20, 115) |
| (10, 55-70, 115) | (10, 110-130, 115) | (10, 170-175, 115) | (10, 0-15, 120) | (10, 60-135, 120) |
| (10, 160-175, 120) | (10, 0-10, 125) | (10, 65-175, 125) | (10, 0-5, 130) | (10, 70-175, 130) |
| (10, 75-175, 135) | (10, 75-175, 140) | (10, 80-175, 145) | (10, 0-10, 150) | (10, 70-175, 150) |
| (10, 0-175, 155) | (10, 0-165, 160) | (10, 0-175, 165) | (10, 0-175, 170) | (10, 0-175, 175) |

TABLE 5
(ϕ[°], θ[°], ψ[°])

| | | | | |
|---|---|---|---|---|
| (15, 0-175, 0) | (15, 0-175, 5) | (15, 90-175, 10) | (15, 105-175, 15) | (15, 110-175, 20) |
| (15, 0-10, 25) | (15, 115-175, 25) | (15, 0-15, 30) | (15, 115-175, 30) | (15, 0-25, 35) |
| (15, 115-175, 35) | (15, 0-25, 40) | (15, 105-175, 40) | (15, 0-30, 45) | (15, 90-170, 45) |
| (15, 0-35, 50) | (15, 75-175, 50) | (15, 0-175, 55) | (15, 0-175, 60) | (15, 0-70, 65) |
| (15, 110-175, 65) | (15, 5-65, 70) | (15, 115-175, 70) | (15, 5-60, 75) | (15, 120-175, 75) |
| (15, 5-60, 80) | (15, 120-140, 80) | (15, 160-175, 80) | (15, 0-60, 85) | (15, 120-135, 85) |
| (15, 165-175, 85) | (15, 0-60, 90) | (15, 120-135, 90) | (15, 170-175, 90) | (15, 0-60, 95) |
| (15, 120-130, 95) | (15, 0-60, 100) | (15, 120-130, 100) | (15, 0-25, 105) | (15, 45-60, 105) |
| (15, 120-130, 105) | (15, 0-20, 110) | (15, 50-65, 110) | (15, 115-130, 110) | (15, 0-15, 115) |
| (15, 55-70, 115) | (15, 110-130, 115) | (15, 175-175, 115) | (15, 0-10, 120) | (15, 60-130, 120) |
| (15, 170-175, 120) | (15, 0-5, 125) | (15, 65-135, 125) | (15, 155-175, 125) | (15, 65-175, 130) |
| (15, 70-175, 135) | (15, 70-175, 140) | (15, 0-5, 145) | (15, 70-175, 145) | (15, 0-35, 150) |
| (15, 50-175, 150) | (15, 0-175, 155) | (15, 0-175, 160) | (15, 0-165, 165) | (15, 0-170, 170) |
| (15, 0-175, 175) | | | | |

TABLE 6
(ϕ[°], θ[°], ψ[°])

| | | | | |
|---|---|---|---|---|
| (20, 0-175, 0) | (20, 95-175, 5) | (20, 115-175, 10) | (20, 120-175, 15) | (20, 0-10, 20) |
| (20, 120-175, 20) | (20, 0-20, 25) | (20, 125-175, 25) | (20, 0-25, 30) | (20, 125-175, 30) |
| (20, 0-30, 35) | (20, 125-175, 35) | (20, 0-35, 40) | (20, 115-175, 40) | (20, 0-35, 45) |
| (20, 95-175, 45) | (20, 0-40, 50) | (20, 65-170, 50) | (20, 0-175, 55) | (20, 0-175, 60) |
| (20, 5-70, 65) | (20, 110-175, 65) | (20, 5-65, 70) | (20, 115-175, 70) | (20, 5-60, 75) |
| (20, 120-175, 75) | (20, 0-60, 80) | (20, 120-175, 80) | (20, 0-60, 85) | (20, 120-140, 85) |
| (20, 160-175, 85) | (20, 0-60, 90) | (20, 120-135, 90) | (20, 165-175, 90) | (20, 0-60, 95) |
| (20, 120-130, 95) | (20, 170-175, 95) | (20, 0-25, 100) | (20, 40-60, 100) | (20, 120-130, 100) |
| (20, 0-20, 105) | (20, 45-60, 105) | (20, 120-130, 105) | (20, 0-15, 110) | (20, 50-65, 110) |
| (20, 115-130, 110) | (20, 0-10, 115) | (20, 55-70, 115) | (20, 110-125, 115) | (20, 0-5, 120) |
| (20, 60-130, 120) | (20, 175-175, 120) | (20, 60-130, 125) | (20, 170-175, 125) | (20, 65-130, 130) |
| (20, 155-175, 130) | (20, 65-175, 135) | (20, 0-5, 140) | (20, 65-175, 140) | (20, 0-25, 145) |
| (20, 60-175, 145) | (20, 0-175, 150) | (20, 0-175, 155) | (20, 0-175, 160) | (20, 0-175, 165) |
| (20, 0-155, 170) | (20, 0-165, 175) | | | |

TABLE 7
(ϕ[°], θ[°], ψ[°])

| | | | | |
|---|---|---|---|---|
| (25, 140-175, 5) | (25, 135-175, 10) | (25, 0-15, 15) | (25, 135-175, 15) | (25, 0-25, 20) |
| (25, 135-175, 20) | (25, 0-30, 25) | (25, 130-175, 25) | (25, 0-35, 30) | (25, 130-175, 30) |
| (25, 0-35, 35) | (25, 130-175, 35) | (25, 0-40, 40) | (25, 125-175, 40) | (25, 0-45, 45) |
| (25, 105-175, 45) | (25, 0-175, 50) | (25, 0-175, 55) | (25, 5-175, 60) | (25, 5-70, 65) |
| (25, 110-175, 65) | (25, 5-65, 70) | (25, 115-175, 70) | (25, 0-60, 75) | (25, 120-175, 75) |
| (25, 0-60, 80) | (25, 120-175, 80) | (25, 0-60, 85) | (25, 120-175, 85) | (25, 0-60, 90) |
| (25, 120-140, 90) | (25, 160-175, 90) | (25, 0-25, 95) | (25, 40-60, 95) | (25, 120-135, 95) |
| (25, 165-175, 95) | (25, 0-20, 100) | (25, 45-60, 100) | (25, 120-130, 100) | (25, 170-175, 100) |
| (25, 0-15, 105) | (25, 50-60, 105) | (25, 120-130, 105) | (25, 0-10, 110) | (25, 55-65, 110) |
| (25, 115-125, 110) | (25, 0-5, 115) | (25, 55-70, 115) | (25, 110-125, 115) | (25, 60-125, 120) |
| (25, 60-125, 125) | (25, 175-175, 125) | (25, 60-125, 130) | (25, 165-175, 130) | (25, 0-5, 135) |
| (25, 60-130, 135) | (25, 145-175, 135) | (25, 60-175, 140) | (25, 0-20, 140) | (25, 0-175, 145) |
| (25, 0-175, 150) | (25, 0-175, 155) | (25, 0-175, 160) | (25, 0-175, 165) | (25, 0-170, 170) |
| (25, 0-130, 175) | | | | |

TABLE 8
(ϕ[°], θ[°], ψ[°])

| | | | | |
|---|---|---|---|---|
| (30, 0-20, 10) | (30, 160-175, 10) | (30, 0-30, 15) | (30, 150-175, 15) | (30, 0-35, 20) |
| (30, 145-175, 20) | (30, 0-40, 25) | (30, 140-175, 25) | (30, 0-40, 30) | (30, 140-175, 30) |
| (30, 0-45, 35) | (30, 135-175, 35) | (30, 0-45, 40) | (30, 135-175, 40) | (30, 0-55, 45) |
| (30, 125-175, 45) | (30, 0-175, 50) | (30, 5-175, 55) | (30, 5-175, 60) | (30, 5-70, 65) |
| (30, 110-175, 65) | (30, 0-65, 70) | (30, 115-175, 70) | (30, 0-60, 75) | (30, 120-175, 75) |
| (30, 0-60, 80) | (30, 120-175, 80) | (30, 0-60, 85) | (30, 120-175, 85) | (30, 0-60, 90) |
| (30, 120-175, 90) | (30, 0-20, 95) | (30, 45-60, 95) | (30, 120-135, 95) | (30, 160-175, 95) |
| (30, 0-15, 100) | (30, 45-60, 100) | (30, 120-135, 100) | (30, 165-175, 100) | (30, 0-10, 105) |
| (30, 50-60, 105) | (30, 120-130, 105) | (30, 170-175, 105) | (30, 0-0, 110) | (30, 55-65, 110) |
| (30, 115-125, 110) | (30, 55-70, 115) | (30, 110-125, 115) | (30, 55-125, 120) | (30, 55-125, 125) |
| (30, 0-5, 130) | (30, 60-120, 130) | (30, 175-175, 130) | (30, 0-15, 135) | (30, 55-125, 135) |
| (30, 165-175, 135) | (30, 0-175, 140) | (30, 0-175, 145) | (30, 0-175, 150) | (30, 0-175, 155) |
| (30, 0-175, 160) | (30, 0-175, 165) | (30, 0-175, 170) | (30, 15-165, 175) | |

TABLE 9
(ϕ[°], θ[°], ψ[°])

| | | | | |
|---|---|---|---|---|
| (35, 0-40, 5) | (35, 0-45, 10) | (35, 0-45, 15) | (35, 165-175, 15) | (35, 0-45, 20) |
| (35, 155-175, 20) | (35, 0-50, 25) | (35, 150-175, 25) | (35, 0-50, 30) | (35, 145-175, 30) |
| (35, 0-50, 35) | (35, 145-175, 35) | (35, 0-55, 40) | (35, 140-175, 40) | (35, 0-75, 45) |
| (35, 135-175, 45) | (35, 5-175, 50) | (35, 5-175, 55) | (35, 5-175, 60) | (35, 0-70, 65) |
| (35, 110-175, 65) | (35, 0-65, 70) | (35, 115-175, 70) | (35, 0-60, 75) | (35, 120-175, 75) |
| (35, 0-60, 80) | (35, 120-175, 80) | (35, 0-60, 85) | (35, 120-175, 85) | (35, 0-20, 90) |
| (35, 40-60, 90) | (35, 120-175, 90) | (35, 0-15, 95) | (35, 45-60, 95) | (35, 120-140, 95) |
| (35, 155-175, 95) | (35, 0-10, 100) | (35, 50-60, 100) | (35, 120-135, 100) | (35, 160-175, 100) |
| (35, 0-0, 105) | (35, 50-60, 105) | (35, 120-130, 105) | (35, 165-175, 105) | (35, 55-65, 110) |
| (35, 115-125, 110) | (35, 170-175, 110) | (35, 55-70, 115) | (35, 110-125, 115) | (35, 175-175, 115) |
| (35, 55-120, 120) | (35, 0-5, 125) | (35, 55-120, 125) | (35, 0-15, 130) | (35, 55-120, 130) |
| (35, 0-35, 135) | (35, 50-120, 135) | (35, 175-175, 135) | (35, 0-120, 140) | (35, 160-175, 140) |
| (35, 0-175, 145) | (35, 0-175, 150) | (35, 0-175, 155) | (35, 0-175, 160) | (35, 0-175, 165) |
| (35, 10-175, 170) | (35, 50-175, 175) | | | |

TABLE 10
(ϕ[°], θ[°], ψ[°])

| | | | | |
|---|---|---|---|---|
| (40, 0-175, 0) | (40, 0-85, 5) | (40, 0-65, 10) | (40, 0-60, 15) | (40, 0-60, 20) |
| (40, 170-175, 20) | (40, 0-55, 25) | (40, 160-175, 25) | (40, 0-55, 30) | (40, 155-175, 30) |
| (40, 0-55, 35) | (40, 150-175, 35) | (40, 0-65, 40) | (40, 145-175, 40) | (40, 5-85, 45) |
| (40, 145-175, 45) | (40, 10-115, 50) | (40, 140-175, 50) | (40, 5-175, 55) | (40, 0-175, 60) |
| (40, 0-70, 65) | (40, 110-175, 65) | (40, 0-65, 70) | (40, 115-175, 70) | (40, 0-60, 75) |
| (40, 120-175, 75) | (40, 0-60, 80) | (40, 120-175, 80) | (40, 0-20, 85) | (40, 40-60, 85) |
| (40, 120-175, 85) | (40, 0-15, 90) | (40, 45-60, 90) | (40, 120-175, 90) | (40, 0-10, 95) |
| (40, 50-60, 95) | (40, 120-175, 95) | (40, 0-0, 100) | (40, 50-60, 100) | (40, 120-140, 100) |
| (40, 155-175, 100) | (40, 50-60, 105) | (40, 120-135, 105) | (40, 160-175, 105) | (40, 50-65, 110) |
| (40, 115-130, 110) | (40, 165-175, 110) | (40, 55-70, 115) | (40, 110-125, 115) | (40, 170-175, 115) |
| (40, 0-5, 120) | (40, 50-120, 120) | (40, 175-175, 120) | (40, 0-10, 125) | (40, 50-120, 125) |
| (40, 0-25, 130) | (40, 50-115, 130) | (40, 0-115, 135) | (40, 0-115, 140) | (40, 175-175, 140) |
| (40, 0-120, 145) | (40, 155-175, 145) | (40, 0-175, 150) | (40, 0-175, 155) | (40, 0-175, 160) |
| (40, 5-175, 165) | (40, 25-175, 170) | (40, 15-175, 175) | | |

TABLE 11
(ϕ[°], θ[°], ψ[°])

| | | | | |
|---|---|---|---|---|
| (45, 0-175, 0) | (45, 0-175, 5) | (45, 0-90, 10) | (45, 0-75, 15) | (45, 0-70, 20) |
| (45, 0-65, 25) | (45, 170-175, 25) | (45, 0-65, 30) | (45, 165-175, 30) | (45, 0-65, 35) |
| (45, 155-175, 35) | (45, 5-75, 40) | (45, 155-175, 40) | (45, 10-90, 45) | (45, 150-175, 45) |
| (45, 5-105, 50) | (45, 145-175, 50) | (45, 0-175, 55) | (45, 0-175, 60) | (45, 0-70, 65) |
| (45, 110-175, 65) | (45, 0-65, 70) | (45, 115-175, 70) | (45, 0-60, 75) | (45, 120-175, 75) |
| (45, 0-20, 80) | (45, 40-60, 80) | (45, 120-175, 80) | (45, 0-15, 85) | (45, 45-60, 85) |
| (45, 120-175, 85) | (45, 0-10, 90) | (45, 45-60, 90) | (45, 120-175, 90) | (45, 0-0, 95) |
| (45, 50-60, 95) | (45, 120-175, 95) | (45, 50-60, 100) | (45, 120-175, 100) | (45, 50-60, 105) |
| (45, 120-135, 105) | (45, 155-175, 105) | (45, 50-65, 110) | (45, 115-130, 110) | (45, 160-175, 110) |
| (45, 0-5, 115) | (45, 50-70, 115) | (45, 110-125, 115) | (45, 165-175, 115) | (45, 0-10, 120) |
| (45, 50-120, 120) | (45, 170-175, 120) | (45, 0-25, 125) | (45, 45-115, 125) | (45, 175-175, 125) |
| (45, 0-115, 130) | (45, 0-110, 135) | (45, 0-110, 140) | (45, 0-110, 145) | (45, 175-175, 145) |
| (45, 0-130, 150) | (45, 145-175, 150) | (45, 0-175, 155) | (45, 5-175, 160) | (45, 15-175, 165) |
| (45, 10-175, 170) | (45, 0-175, 175) | | | |

TABLE 12
(ϕ[°], θ[°], ψ[°])

| | | | | |
|---|---|---|---|---|
| (50, 0-175, 0) | (50, 0-175, 5) | (50, 0-175, 10) | (50, 0-95, 15) | (50, 0-80, 20) |
| (50, 0-75, 25) | (50, 0-70, 30) | (50, 175-175, 30) | (50, 5-70, 35) | (50, 165-175, 35) |
| (50, 10-80, 40) | (50, 160-175, 40) | (50, 5-95, 45) | (50, 155-175, 45) | (50, 0-105, 50) |
| (50, 150-175, 50) | (50, 0-120, 55) | (50, 145-175, 55) | (50, 0-175, 60) | (50, 0-70, 65) |
| (50, 110-175, 65) | (50, 0-65, 70) | (50, 115-175, 70) | (50, 0-25, 75) | (50, 40-60, 75) |
| (50, 120-175, 75) | (50, 0-15, 80) | (50, 45-60, 80) | (50, 120-175, 80) | (50, 0-10, 85) |
| (50, 45-60, 85) | (50, 120-175, 85) | (50, 0-0, 90) | (50, 50-60, 90) | (50, 120-175, 90) |
| (50, 50-60, 95) | (50, 120-175, 95) | (50, 50-60, 100) | (50, 120-175, 100) | (50, 50-60, 105) |
| (50, 120-175, 105) | (50, 0-5, 110) | (50, 50-65, 110) | (50, 115-135, 110) | (50, 155-175, 110) |
| (50, 0-10, 115) | (50, 50-70, 115) | (50, 110-125, 115) | (50, 160-175, 115) | (50, 0-20, 120) |
| (50, 45-120, 120) | (50, 165-175, 120) | (50, 0-115, 125) | (50, 170-175, 125) | (50, 0-110, 130) |
| (50, 175-175, 130) | (50, 0-105, 135) | (50, 0-105, 140) | (50, 0-100, 145) | (50, 0-110, 150) |
| (50, 170-175, 150) | (50, 5-175, 155) | (50, 15-175, 160) | (50, 5-175, 165) | (50, 0-175, 170) |
| (50, 0-175, 175) | | | | |

TABLE 13
(ϕ[°], θ[°], ψ[°])

| | | | | |
|---|---|---|---|---|
| (55, 0-175, 0) | (55, 0-175, 5) | (55, 0-175, 10) | (55, 0-125, 15) | (55, 155-175, 15) |
| (55, 0-95, 20) | (55, 0-85, 25) | (55, 5-80, 30) | (55, 10-80, 35) | (55, 175-175, 35) |
| (55, 5-90, 40) | (55, 165-175, 40) | (55, 0-95, 45) | (55, 160-175, 45) | (55, 0-105, 50) |
| (55, 155-175, 50) | (55, 0-115, 55) | (55, 150-175, 55) | (55, 0-130, 60) | (55, 145-175, 60) |
| (55, 0-70, 65) | (55, 110-175, 65) | (55, 0-25, 70) | (55, 40-65, 70) | (55, 115-175, 70) |
| (55, 0-15, 75) | (55, 45-60, 75) | (55, 120-175, 75) | (55, 0-10, 80) | (55, 45-60, 80) |
| (55, 120-175, 80) | (55, 0-0, 85) | (55, 50-60, 85) | (55, 120-175, 85) | (55, 50-60, 90) |
| (55, 120-175, 90) | (55, 50-60, 95) | (55, 120-175, 95) | (55, 50-60, 100) | (55, 120-175, 100) |
| (55, 0-0, 105) | (55, 50-60, 105) | (55, 120-175, 105) | (55, 0-10, 110) | (55, 45-65, 110) |
| (55, 115-175, 110) | (55, 0-20, 115) | (55, 45-70, 115) | (55, 110-130, 115) | (55, 155-175, 115) |
| (55, 0-120, 120) | (55, 160-175, 120) | (55, 0-115, 125) | (55, 165-175, 125) | (55, 0-110, 130) |
| (55, 170-175, 130) | (55, 0-105, 135) | (55, 175-175, 135) | (55, 0-100, 140) | (55, 0-95, 145) |
| (55, 5-95, 150) | (55, 10-110, 155) | (55, 170-175, 155) | (55, 5-175, 160) | (55, 0-175, 165) |
| (55, 0-175, 170) | (55, 0-175, 175) | | | |

TABLE 14
(ϕ[°], θ[°], ψ[°])

| | | | | |
|---|---|---|---|---|
| (60, 0-175, 0) | (60, 0-175, 5) | (60, 0-175, 10) | (60, 0-175, 15) | (60, 0-115, 20) |
| (60, 165-175, 20) | (60, 5-95, 25) | (60, 10-90, 30) | (60, 5-90, 35) | (60, 0-95, 40) |
| (60, 175-175, 40) | (60, 0-100, 45) | (60, 170-175, 45) | (60, 0-105, 50) | (60, 165-175, 50) |
| (60, 0-115, 55) | (60, 160-175, 55) | (60, 0-125, 60) | (60, 155-175, 60) | (60, 0-30, 65) |
| (60, 40-70, 65) | (60, 110-135, 65) | (60, 145-175, 65) | (60, 0-15, 70) | (60, 45-65, 70) |
| (60, 115-175, 70) | (60, 0-10, 75) | (60, 45-60, 75) | (60, 120-175, 75) | (60, 0-0, 80) |
| (60, 50-60, 80) | (60, 120-175, 80) | (60, 50-60, 85) | (60, 120-175, 85) | (60, 50-60, 90) |
| (60, 120-175, 90) | (60, 50-60, 95) | (60, 120-175, 95) | (60, 0-0, 100) | (60, 50-60, 100) |
| (60, 120-175, 100) | (60, 0-10, 105) | (60, 45-60, 105) | (60, 120-175, 105) | (60, 0-15, 110) |
| (60, 45-65, 110) | (60, 115-175, 110) | (60, 0-30, 115) | (60, 40-70, 115) | (60, 110-135, 115) |
| (60, 145-175, 115) | (60, 0-125, 120) | (60, 155-175, 120) | (60, 0-115, 125) | (60, 160-175, 125) |
| (60, 0-105, 130) | (60, 165-175, 130) | (60, 0-100, 135) | (60, 170-175, 135) | (60, 0-95, 140) |
| (60, 175-175, 140) | (60, 5-90, 145) | (60, 10-90, 150) | (60, 5-95, 155) | (60, 0-115, 160) |
| (60, 165-175, 160) | (60, 0-175, 165) | (60, 0-175, 170) | (60, 0-175, 175) | |

Despite when the Euler angles of the crystal substrate 3 are within the range of the Euler angles equivalent to the range of (φ, θ, ψ) in Table 2 to Table 14, a bulk wave that propagates through the crystal substrate 3 has a lower velocity than an acoustic wave that propagates through the lithium tantalate layer 6. The symmetry of quartz crystal is D₃⁶ or D₃⁴ in Schoenflies notation, or a point group of 32 in international notation. Hiroshi KAMEYAMA, Symmetry of Elastic Vibration in Quartz crystal, Japanese Journal of Applied Physics, Volume 23, Number S1 describes that crystal has high symmetry with respect to the polar coordinates (θ, φ). The following description expresses that various features f (θ, φ) relating to the acoustic vibration such as velocity, an elastic constant, displacement, or a frequency constant are unchangeable by the symmetry operation.

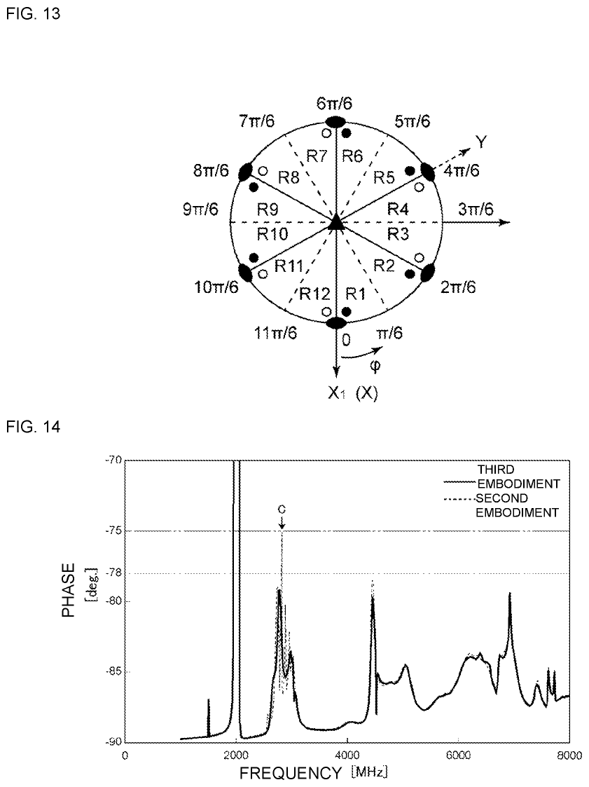

FIG. 13 is a stereographic projection showing symmetry of acoustic vibrations in quartz crystal. In FIG. 13, an inversion operation I is added to the symmetry operation on the crystal point group D₃-32, and the stereographic projection is thus the same as the stereographic projection of the crystal point group D_{3d}-3m (with a bar above 3). In FIG. 13, black circular plots indicate equivalent points of the upper hemisphere, white circular plots indicate equivalent points of the lower hemisphere, elliptical plots indicate two-rotation axes, and a triangular plot indicates a three-rotation axis.

The three-rotation axis in FIG. 13 corresponds to the Z axis in notation of the Euler angles. In FIG. 13, multiple axes such as about 0° or about 60° (about 2π/6) extend perpendicularly to the Z axis. As illustrated in FIG. 13, quartz crystal exhibits the same behavior of the acoustic vibration every time when rotating about the Z axis in a direction of φ by about 120° (about 4π/6). Thus, the velocity at about 0° to about 60° and the velocity at about 60° to about 120° form symmetry with respect to the axis of about 60°. Thus, as illustrated in Table 2 to Table 14, showing the orientations of the Euler angles when φ is about 0° to about 60° can express the characteristics of all the orientations (all the Euler angles) of crystal while other orientations are regarded as being equivalent to the above orientations. The equivalent orientations include the following angles in 1) and 2). 1) Euler angles when rotated by about 0°, about 120°, or about 240° in the direction of φ about the Z axis. 2) Euler angles when rotated by about 60°, about 180°, or about 300° in the direction of φ about the Z axis and then subjected to the inversion operation (reverse relationship of the crystal substrate).

Hereafter, an effect of effectively reducing a higher order mode in a wide band with a bulk wave that propagates through the crystal substrate 3 having a lower velocity than an acoustic wave that propagates through the lithium tantalate layer 6 is described in detail.

With reference to FIG. 1, a second preferred embodiment and a third preferred embodiment of the present invention are described. The second preferred embodiment differs from the first preferred embodiment in that a bulk wave that propagates through the crystal substrate 3 has a higher velocity than an acoustic wave that propagates through the lithium tantalate layer 6. More specifically, the second preferred embodiment differs from the first preferred embodiment in the Euler angles (φ, θ, ψ) of the crystal substrate 3. The acoustic wave device according to the third preferred embodiment differs from an acoustic wave device in which the Euler angles (φ, θ, ψ) of the crystal substrate 3 have the phase characteristics illustrated in FIG. 4. The acoustic wave device according to the third preferred embodiment substantially has the same structure as the acoustic wave device according to the first preferred embodiment.

The acoustic wave device according to the second preferred embodiment and the acoustic wave device according to the third preferred embodiment are compared in terms of the phase characteristics. The design parameters of the acoustic wave devices are as follows.
silicon carbide layer 4: a thickness of 2 μm
low velocity film 5: a material of SiO₂ and a thickness of 300 nm
lithium tantalate layer 6: a material of LiTaO₃ and a thickness of 400 nm

IDT electrode 7: a layer structure including a Ti layer, an AlCu layer, and a Ti layer sequentially laminated on the lithium tantalate layer 6, thicknesses of 12 nm, 100 nm, and 4 nm from the side closer to the lithium tantalate layer 6, a wavelength λ of 2 μm, and a duty of 0.5

In the second preferred embodiment, the Euler angles (φ, θ, ψ) of the crystal substrate 3 are set as (about 0°, about 180°, about 90°). In this case, a slow transversal wave that propagates through the crystal substrate 3 has a velocity of about 3915.4 m/s. A surface acoustic wave that propagates through the lithium tantalate layer 6 has a velocity of about 3914.2 m/s. Thus, the slow transversal wave that propagates through the crystal substrate 3 has a higher velocity than the surface acoustic wave that propagates through the lithium tantalate layer 6.

In the third preferred embodiment, the Euler angles (φ, θ, ψ) of the crystal substrate 3 are set as (about 0°, about 200°, about 60°). In this case, a slow transversal wave that propagates through the crystal substrate 3 has a velocity of about 3538.2 m/s. A surface acoustic wave that propagates through the lithium tantalate layer 6 has a velocity of about 3914.2 m/s. Thus, the slow transversal wave that propagates through the crystal substrate 3 has a lower velocity than the surface acoustic wave that propagates through the lithium tantalate layer 6.

FIG. 14 is a diagram showing the phase characteristics of the acoustic wave devices according to the second preferred embodiment and the third preferred embodiment.

As illustrated in FIG. 14, in the second preferred embodiment, the higher order mode can be reduced to be smaller than about −78 deg. except in the band indicated with arrow C. In the second preferred embodiment, the higher order mode can be reduced to be smaller than or equal to about −75 deg. also in the band indicated with arrow C. In the third preferred embodiment, on the other hand, the higher order mode can be reduced to be smaller than −78 deg. in a wide band including the band indicated with arrow C. Thus, in the second and third preferred embodiments, the crystal substrate 3 can leak a higher order mode, and can thus further efficiently reduce the higher order mode in a wide band.

While preferred embodiments of the present invention have been described above, it is to be understood that variations and modifications will be apparent to those skilled in the art without departing from the scope and spirit of the present invention. The scope of the present invention, therefore, is to be determined solely by the following claims.

What is claimed is:

1. An acoustic wave device comprising:
a crystal substrate;
a silicon carbide layer on the crystal substrate;
a piezoelectric layer on the silicon carbide layer; and
an interdigital transducer (IDT) electrode on the piezoelectric layer and including a plurality of electrode fingers.

2. The acoustic wave device according to claim 1, wherein the piezoelectric layer is a lithium tantalate layer or a lithium niobate layer.

3. The acoustic wave device according to claim 2, wherein the piezoelectric layer has a cut-angle of about 20°-rotated Y-cut X-propagation to about 60°-rotated Y-cut X-propagation.

4. The acoustic wave device according to claim 1, further comprising:
a low velocity film between the silicon carbide layer and the piezoelectric layer; wherein
a bulk wave that propagates through the low velocity film has a lower velocity than a bulk wave that propagates through the piezoelectric layer.

5. The acoustic wave device according to claim 4, wherein the low velocity film is a silicon oxide film.

6. The acoustic wave device according to claim 1, wherein a bulk wave that propagates through the crystal substrate has a lower velocity than an acoustic wave that propagates through the piezoelectric layer.

7. The acoustic wave device according to claim 6, wherein the crystal substrate has Euler angles (φ, θ, ψ) of (about 0±2.5°, θ, about 90°±2.5°), and θ in the Euler angles of the crystal substrate satisfies about 185°≤θ≤ about 240°.

8. The acoustic wave device according to claim 7, wherein
the IDT electrode includes a plurality of electrode fingers; and
when a wavelength defined by an electrode finger pitch of the IDT electrode is denoted with Δ and a thickness of the silicon carbide layer is denoted with t, a relationship between θ in the Euler angles of the crystal substrate and the thickness t is any of combinations in Table 1:
TABLE 1

| θ [°] of | thickness t [λ] of |
|---|---|
| crystal substrate | silicon carbide layer |
| 185 ≤ θ < 185.5 | 0.75 ≤ t ≤ 1.15 |
| 185.5 ≤ θ < 186.5 | 0.75 ≤ t ≤ 1.2 |
| | 1.7 ≤ t ≤ 1.9 |
| 186.5 ≤ θ < 187.5 | 0.6 ≤ t ≤ 1.2 |
| | 1.5 ≤ t ≤ 1.85 |
| 187.5 ≤ θ < 188.5 | 0.8 ≤ t ≤ 1.15 |
| | 1.4 ≤ t ≤ 1.75 |
| 188.5 ≤ θ < 189.5 | 0.6 ≤ t ≤ 1.2 |
| 189.5 ≤ θ < 190 | 0.6 ≤ t ≤ 1.7 |
| 190 ≤ θ < 192.5 | 0.6 ≤ t ≤ 1.7 |
| 192.5 ≤ θ < 197.5 | 0.6 ≤ t ≤ 1.65 |
| 197.5 ≤ θ < 202.5 | 0.6 ≤ t ≤ 1.6 |
| 202.5 ≤ θ < 207.5 | 0.6 ≤ t ≤ 1.6 |
| 207.5 ≤ θ < 212.5 | 0.6 ≤ t ≤ 1.6 |
| 212.5 ≤ θ < 217.5 | 0.6 ≤ t ≤ 1.6 |
| 217.5 ≤ θ < 222.5 | 0.6 ≤ t ≤ 1.6 |
| 222.5 ≤ θ < 227.5 | 0.6 ≤ t ≤ 1.65 |
| 227.5 ≤ θ < 232.5 | 0.6 ≤ t ≤ 1.7 |
| 232.5 ≤ θ < 237.5 | 0.6 ≤ t ≤ 1.75 |
| 237.5 ≤ θ ≤ 240 | 0.6 ≤ t ≤ 1.85 |

9. The acoustic wave device according to claim 1, further comprising reflectors on opposite ends of the IDT electrode.

10. The acoustic wave device according to claim 1, wherein the acoustic wave device is a surface acoustic wave resonator.

11. The acoustic wave device according to claim 1, wherein the acoustic wave device is a multiplexer or a filter device.

12. The acoustic wave device according to claim 4, wherein the low velocity film includes at least one of glass, a silicon oxynitride, a lithium oxide, a tantalum pentoxide, or a compound obtained by adding fluorine, carbon, or boron to a silicon oxide as a main component.

13. The acoustic wave device according to claim 1, wherein the acoustic wave device is structured such that a bulk wave propagates through the crystal substrate and has a lower velocity than an acoustic wave that propagates through the piezoelectric layer.

14. The acoustic wave device according to claim 1, wherein the acoustic wave device is structured such that a slow transversal wave propagates through the crystal substrate and has a lower velocity than a surface acoustic wave that propagates through the piezoelectric layer.

15. The acoustic wave device according to claim 1, wherein the IDT electrode includes a multilayer metal film or a single layer metal film.

16. The acoustic wave device according to claim 1, wherein a thickness of the piezoelectric layer is smaller than or equal to about 1λ, where λ is a wavelength defined by an electrode finger pitch of the IDT electrode.

17. The acoustic wave device according to claim 1, wherein a mode of frequencies around 2.2 times of a resonant frequency is a leaky mode.

18. The acoustic wave device according to claim 1, wherein a bulk wave that propagates through the crystal substrate has a higher velocity than an acoustic wave that propagates through the piezoelectric layer.

19. The acoustic wave device according to claim 1, wherein the crystal substrate has Euler angles of (φ, θ, ψ) of about 0°, about 180°, about 90°.

20. The acoustic wave device according to claim 1, wherein the crystal substrate has Euler angles of (φ, θ, ψ) about 0°, about 200°, about 60°.
